(19) United States
(12) Patent Application Publication
(10) Pub. No.: US 2025/0331162 A1
(43) Pub. Date: Oct. 23, 2025

(54) SEMICONDUCTOR DEVICE HAVING BURIED GATE ELECTRODE

(71) Applicant: SAMSUNG ELECTRONICS CO., LTD., SUWON-SI (KR)

(72) Inventors: Jihoon Kim, Suwon-si (KR); Suhyun Kim, Suwon-si (KR); Hongmin Seo, Suwon-si (KR); Yeonju Oh, Suwon-si (KR); Dongju Chang, Suwon-si (KR); Seohyeong Jang, Suwon-si (KR)

(21) Appl. No.: 19/006,772

(22) Filed: Dec. 31, 2024

(30) Foreign Application Priority Data
Apr. 18, 2024 (KR) 10-2024-0052091

(51) Int. Cl. H10B 12/00

(52) U.S. Cl. CPC H10B 12/34; H10B 12/053

(57) ABSTRACT

A semiconductor device includes a substrate including active regions, a gate structure crossing the active regions of the substrate and extending in a first horizontal direction, and a bit line structure extending across the gate structure in a second horizontal direction, intersecting the first horizontal direction. The gate structure includes a first gate electrode layer disposed on the substrate, an intermediate conductive layer disposed on the first gate electrode layer, and a second gate electrode layer disposed on the intermediate conductive layer. The intermediate conductive layer includes a grain portion having a crystal orientation that is substantially perpendicular to an upper surface of the first gate electrode layer.

### CROSS-REFERENCE TO RELATED APPLICATION(S)

This application claims priority under 35 USC 119(a) of Korean Patent Application No. 10-2024-0052091, filed on Apr. 18, 2024, in the Korean Intellectual Property Office, the entire disclosure of which is herein incorporated by reference for all purposes.

### BACKGROUND

### 1. Technical Field

The present inventive concept relates to a buried gate electrode of a semiconductor device, and more particularly to a buried gate electrode having an intermediate conductive layer.

### 2. Discussion of Related Art

A degree of integration of semiconductor devices may be increased to meet increasing demands for high performance, speed, and/or multifunctionality of semiconductor devices. The degree of integration of semiconductor devices may be increased by manufacturing fine-patterned semiconductor devices in which patterns have fine widths and/or fine spacings.

### SUMMARY

Example embodiments provide a semiconductor device including a gate electrode layer, in which deterioration due to surface roughness and growth distribution may be reduced.

According to example embodiments, a semiconductor device includes a substrate including an active region; a gate trench disposed in the substrate, the gate trench extending in a first horizontal direction across the active region; and a gate structure disposed in the gate trench. The gate structure includes a buried gate electrode disposed in the gate trench; a gate capping layer disposed in the gate trench on the buried gate electrode; and a gate dielectric layer disposed between the buried gate electrode and the gate trench and between the gate capping layer and the gate trench. The buried gate electrode includes a first gate electrode layer; a second gate electrode layer disposed on the first gate electrode layer; and an intermediate conductive layer between the first gate electrode layer and the second gate electrode layer.

According to example embodiments, a semiconductor device includes a substrate including active regions; a gate structure crossing the active regions of the substrate and extending in a first horizontal direction; and a bit line structure extending across the gate structure in a second horizontal direction, intersecting the first horizontal direction. The gate structure includes a first gate electrode layer disposed on the substrate; an intermediate conductive layer disposed on the first gate electrode layer; and a second gate electrode layer disposed on the intermediate conductive layer. The intermediate conductive layer includes a grain portion having a crystal orientation that is substantially perpendicular to an upper surface of the first gate electrode layer.

According to example embodiments, a semiconductor device includes a substrate including an active region; a gate trench disposed in the substrate, the gate trench extending across the active region in a first horizontal direction; a gate structure disposed in the gate trench; a bit line structure extending across the gate structure, in a second horizontal direction, intersecting the first horizontal direction; a contact plug disposed on a side surface of the bit line structure; a landing pad disposed on the contact plug; and a capacitor structure electrically connected to the landing pad. The gate structure includes a buried gate electrode disposed in the gate trench; a gate capping layer disposed in the gate trench and on the buried gate electrode; and a gate dielectric layer disposed between the buried gate electrode and the gate trench and between the gate capping layer and the gate trench. The buried gate electrode includes a first gate electrode layer; a second gate electrode layer on an upper surface of the first gate electrode layer; a third gate electrode layer on an upper surface of the second gate electrode layer; and an intermediate conductive layer between the upper surface of the first gate electrode layer and a lower surface of the second gate electrode layer. A side surface of the first gate electrode layer, a side surface of the second gate electrode layer, a side surface of the third gate electrode layer, and a side surface of the intermediate conductive layer are in contact with the gate dielectric layer. The first gate electrode layer includes a first TiN including a grain portion having a crystal orientation substantially parallel to an upper surface of the substrate. The intermediate conductive layer includes a second TiN different from the first TIN and including a grain portion having a crystal orientation substantially perpendicular to the upper surface of the substrate.

### BRIEF DESCRIPTION OF DRAWINGS

Aspects, features, and advantages of the present inventive concept will be more clearly understood from the following detailed description, taken in conjunction with the accompanying drawings, in which:

FIG. 1 is a plan view illustrating a semiconductor device according to an example embodiment;

FIG. 2A is a vertical cross-sectional view taken along lines II-I′ and II-II′ of the semiconductor device illustrated in FIG. 1;

FIG. 2B is a vertical cross-sectional view taken along line III-III′ of the semiconductor device illustrated in FIG. 1;

FIG. 2C is a vertical cross-sectional view taken along line IV-IV′ of the semiconductor device illustrated in FIG. 1;

FIG. 3A is an enlarged view of a portion of the semiconductor device illustrated in FIG. 2B;

FIG. 3B is an enlarged view of a portion of the semiconductor device illustrated in FIG. 2C;

FIG. 4 is an enlarged view of a portion of a semiconductor device according to example embodiments;

FIG. 5 is an enlarged view of a portion of a semiconductor device according to example embodiments;

FIG. 6 is a partially enlarged view illustrating a semiconductor device according to example embodiments;

FIG. 7 is a vertical cross-sectional view taken along line IV-IV′ of the semiconductor device illustrated in FIG. 1;

FIG. 8 is an enlarged view of a portion of the semiconductor device illustrated in FIG. 7; and

FIGS. 9A to 9C, 10A to 10C, 11A to 11C, 12A to 12C, 13A to 13C, 14A to 14C, and 15A to 15C are vertical cross-sectional views illustrated according to a process sequence to describe a method of manufacturing a semiconductor device according to an example embodiment.

### DETAILED DESCRIPTION

In the following detailed description, reference is made to the accompanying drawings that show, by way of illustration, embodiments that may be practiced. Embodiments are described in sufficient detail to enable those skilled in the art to practice embodiments of the present disclosure. It is to be understood that various embodiments of the present disclosure, although different, are not necessarily mutually exclusive. For example, a certain feature, structure, or characteristic described herein in connection with an embodiment may be implemented within other embodiments without departing from the spirit and scope of the present disclosure. In addition, it is to be understood that the location or arrangement of individual elements within an embodiment may be modified without departing from the spirit and scope of the present disclosure. The following detailed description is, therefore, not to be taken in a limiting sense, and the scope of the present disclosure is defined only by the appended claims, appropriately interpreted, along with the full range of equivalents to which the claims are entitled. In the drawings, like numerals refer to the same or similar elements or functionality throughout the several views.

Hereinafter, terms such as “upper,” “middle,” “intermediate,” “lower,” “first,” “second,” “third” and the like, may be used to describe components of the specification. These terms may be used to describe various components, but the components are not limited by the terms. For example, the “first component” may be referred to as the “second component.”

Hereinafter, example embodiments will be described with reference to the accompanying drawings.

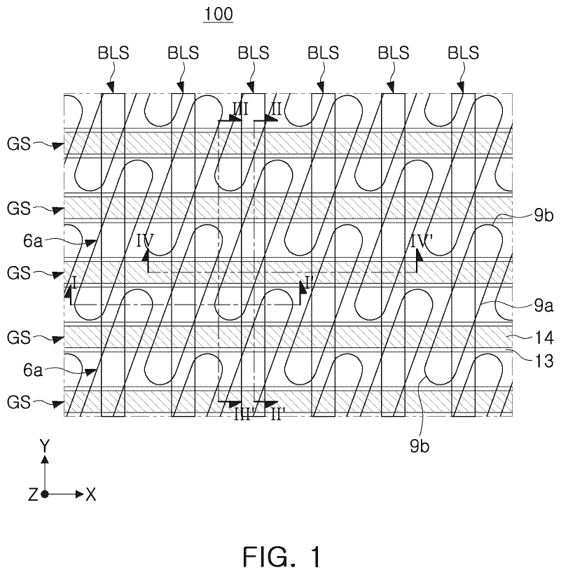

FIG. 1 is a plan view illustrating a semiconductor device according to an example embodiment.

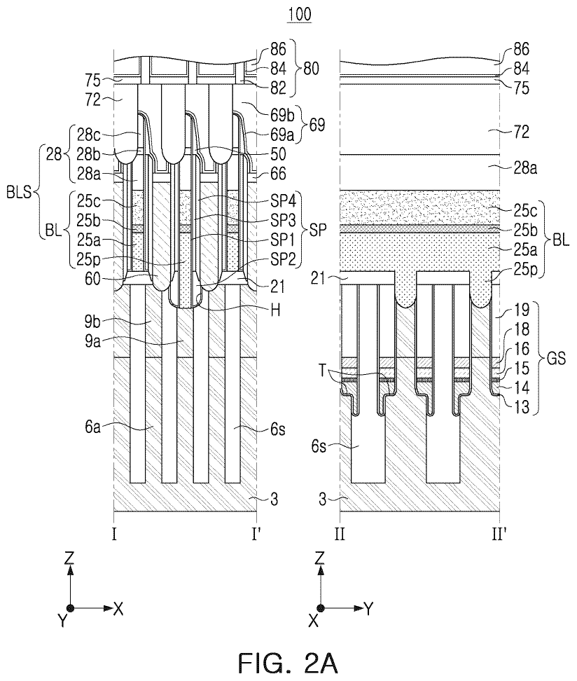

FIG. 2A shows vertical cross-sectional views taken along lines II-I′ and II-II′ of the semiconductor device illustrated in FIG. 1. FIG. 2B is a vertical cross-sectional view taken along line III-III′ of the semiconductor device illustrated in FIG. 1. FIG. 2C is a vertical cross-sectional view along line IV-IV′ of the semiconductor device illustrated in FIG. 1.

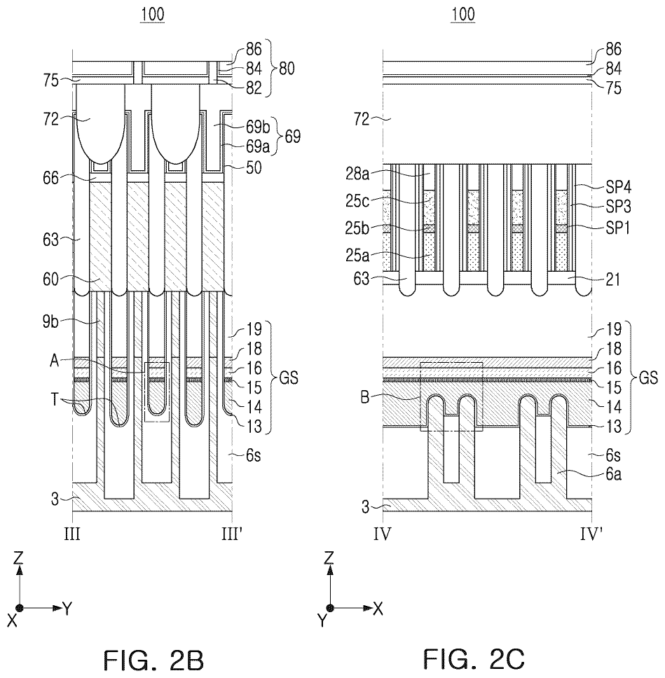

FIG. 3A is an enlarged view of a portion of the semiconductor device illustrated in FIG. 2B. FIG. 3A may correspond to area ‘A’ in FIG. 2B. FIG. 3B is an enlarged view of a portion of the semiconductor device illustrated in FIG. 2C. FIG. 3B may correspond to area ‘B’ in FIG. 2C.

Referring to FIGS. 1, 2A to 2C, and 3A to 3B, a semiconductor device 100 according to an example embodiment may include a substrate 3, a gate structure GS, a buffer layer 21, a bit line structure BLS, a spacer structure SP, a contact plug 60, a landing pad 69, and a capacitor structure 80.

The substrate 3 may include a semiconductor material, such as a group IV semiconductor, a group III-V compound semiconductor, or a group II-VI compound semiconductor. For example, a group IV semiconductor may include silicon, germanium, or silicon-germanium. The substrate 3 may be a silicon substrate, a silicon on insulator (SOI) substrate, a germanium substrate, a germanium on insulator (GOI) substrate, a silicon-germanium substrate, or a substrate including an epitaxial layer.

The substrate 3 may include an active region 6a, a device isolation layer 6s, a first impurity region 9a, and a second impurity region 9b. The device isolation layer 6s may be an insulating layer extending downward from an upper surface of the substrate 3. The device isolation layer 6s may define the active region 6a. For example, the active region 6a may correspond to a portion of the upper surface of the substrate 3 surrounded by the device isolation layer 6s. In plan view, the active region 6a may have a bar shape with a minor axis and a major axis, and may extend in an inclined direction with respect to the X-direction and the Y-direction (see FIG. 1).

The active region 6a may include first and second impurity regions 9a and 9b extending from the upper surface of the substrate 3 to a predetermined depth in the substrate 3. The first and second impurity regions 9a and 9b may be spaced apart from each other. The first and second impurity regions 9a and 9b may serve as source/drain regions of the transistor. For example, for an active region 6a, two gate structures GS may cross the active region 6a, a drain region may be formed between the two gate structures GS, and source regions may be formed in regions opposite to the drain region for the two gate structures GS. For example, the first impurity region 9a may correspond to the drain region, and the second impurity region 9b may correspond to the source region. The source region and the drain region formed by first and second impurity regions 9a and 9b may be formed by doping or ion implantation. For example, the source region and the drain region formed by first and second impurity regions 9a and 9b may be formed by doping or ion implantation of substantially the same impurities. The source region and the drain region may be referred to interchangeably depending on the circuit configuration of the transistor that is formed. The first and second impurity regions 9a and 9b may include impurities having a conductivity type opposite to that of the substrate 3. For example, the active regions 6a may contain p-type impurities, and the first and second impurity regions 9a and 9b may contain n-type impurities. The device isolation layer 6s may extend downward from the upper surface of the substrate 3 and may define active regions 6a. The device isolation layer 6s may surround the active region 6a. The device isolation layer 6s may space different active regions apart from each other. The device isolation layer 6s may include silicon oxide, silicon nitride, or silicon oxynitride, or combinations thereof. The device isolation layer 6s may be formed of a single layer or multiple layers.

In a top view, the gate structures GS may extend in the X-direction and may be spaced apart from each other in the Y-direction. Additionally, the gate structures GS may cross the active region 6a. For example, two gate structures GS may intersect in an active region 6a. The transistors including the gate structure GS and the first and second impurity regions 9a and 9b, respectively, may form a buried channel array transistor (BCAT), but are not limited thereto.

In the cross-sectional view, the gate structures GS may be buried within the substrate 3. For example, the gate structures GS may be disposed inside a gate trench T formed within the substrate 3. Accordingly, the gate structures GS may be called buried gate structures.

The gate structure GS may include a gate dielectric layer 13, a buried gate electrode, an upper pattern 18, and a gate capping layer 19. The gate dielectric layer 13 may be disposed inside the gate trench T. The buried gate electrode may include a plurality of lower patterns (e.g., 14, 15, and 16). The plurality of lower patterns (e.g., 14, 15, and 16) of the buried gate electrode may be sequentially stacked on gate dielectric layer 13. The upper pattern 18 may be disposed on the buried gate electrode. The gate capping layer 19 may be disposed on the upper pattern 18.

The gate dielectric layer 13 may be formed conformally on the inner wall of the gate trench T. The gate dielectric layer 13 may include silicon oxide or a material with a high dielectric constant. In example embodiments, the gate dielectric layer 13 may be a layer formed by oxidation of the active region 6a, or may be a layer formed by deposition.

The buried gate electrode may include a plurality of lower patterns (e.g., 14, 15, and 16). The plurality of lower patterns may include a first gate electrode layer 14, an intermediate layer 15, and a second gate electrode layer 16. The lower patterns may fill at least a portion of the lower region of the gate trench T and may be sequentially stacked in the vertical direction (for example, Z-direction) from a lower surface of the gate dielectric layer 13. The lower patterns may be collectively referred to as gate electrodes.

The first gate electrode layer 14 may be disposed in a lower portion of the gate trench T. The first gate electrode layer 14 may contact the lower surface of the gate dielectric layer 13 and a lower region of a sidewall at the lower portion of the gate trench T. The first gate electrode layer 14 may be formed of a conductive material, and may include at least one of, for example, polycrystalline silicon (Si), titanium (Ti), titanium nitride (TiN), tantalum (Ta), tantalum nitride (TaN), tungsten (W), tungsten nitride (WN), molybdenum (Mo), molybdenum nitride (MoN), ruthenium (Ru), or aluminum (Al). In an embodiment, the first gate electrode layer 14 may include titanium nitride (TiN). Meanwhile, the first gate electrode layer 14 may be called a first buried gate electrode layer.

The intermediate layer 15 may be disposed on the first gate electrode layer 14. The intermediate layer 15 may contact the sidewall of the gate dielectric layer 13 on the first gate electrode layer 14. The intermediate layer 15 may be formed of a conductive material, and may include at least one of polycrystalline silicon (Si), titanium (Ti), titanium nitride (TiN), tantalum (Ta), tantalum nitride (TaN), tungsten (W), tungsten nitride (WN)., molybdenum (Mo), molybdenum nitride (MoN), ruthenium (Ru), or aluminum (Al). Accordingly, the intermediate layer 15 may be referred to as an intermediate conductive layer. In an embodiment, the intermediate layer 15 may include titanium nitride (TiN). The thickness d1 of the intermediate layer 15 may be thinner than the thickness of the first and second gate electrode layers 14 and 16 and thicker than the thickness of the gate dielectric layer 13. In an example, the thickness dl of intermediate layer 15 may range from approximately 5 Angstrom (Å) to approximately 100 Å. In an example, the thickness d1 of intermediate layer 15 may range from approximately 5 Å to approximately 50 Å.

The second gate electrode layer 16 may be disposed on the intermediate layer 15. The second gate electrode layer 16 may contact the sidewall of the gate dielectric layer 13 on the intermediate layer 15. The second gate electrode layer 16 may be formed of a conductive material, and may include at least one of polycrystalline silicon (Si), titanium (Ti), titanium nitride (TiN), tantalum (Ta), tantalum nitride (TaN), tungsten (W), tungsten nitride. (WN), molybdenum (Mo), molybdenum nitride (MoN), ruthenium (Ru), or aluminum (Al). In an embodiment, the second gate electrode layer 16 may include at least one of tungsten (W) or molybdenum (Mo). Meanwhile, the second gate electrode layer 16 may be called a second buried gate electrode layer.

Herein, reference is made to grains having crystal orientation. It should be understood that a structure of a metal may be made up of individual crystalline areas called as grains. The crystal orientation of a material may be understood in terms of a horizontal width and a vertical height of the grains. For example, in a material having a horizontal crystal orientation, the grains of the material may have a horizontal width greater than a vertical height. Similarly, in a material having a vertical crystal orientation, the grains of the material may have a horizontal width less than a vertical height.

Each of the first gate electrode layer 14, the intermediate layer 15, and the second gate electrode layer 16 may include grains G1, Gm, and G2. In this case, each of the grains G1, Gm, and G2 may include grain portions G1p, Gmp, and G2p corresponding to a crystal region each having the same crystal orientation. For example, the first gate electrode layer 14 includes a first grain G1 having at least one first grain portion G1p, the second gate electrode layer 16 includes a second grain G2 having at least one second grain portion G2p, and the intermediate layer 15 may include a third grain Gm having at least one third grain portion Gmp.

For example, the first gate electrode layer 14 may include a first metal grain having a first metal grain portion, and the second gate electrode layer 16 may include a second metal grain having a second metal grain portion, wherein the first metal grain portion has a crystal orientation substantially parallel to an upper surface of a substrate, and the second metal grain portion has a crystal orientation substantially perpendicular to an upper surface of the intermediate layer 15. Substantially parallel or substantially perpendicular may refer to an orientation of grains, for example, in a material having a crystal orientation substantially parallel to an upper surface of a substrate, greater than 50% or more of the grains may have a horizontal width greater than a vertical height, greater than 60% or more of the grains may have a horizontal width greater than a vertical height, or greater than 80% or more of the grains may have a horizontal width greater than a vertical height.

The crystal orientation of the first grain portion G1p may be horizontal. Accordingly, a maximum horizontal width G1h of the first grain portion G1p may be greater than a maximum vertical width G1v (or ‘maximum vertical thickness’). The maximum horizontal width G1h may be defined as the maximum value of the width along one horizontal direction (for example, X-direction and/or Y-direction) of the first grain portion G1p, and the maximum vertical width G1v may be defined as the maximum value of the width along the vertical direction (for example, Z-direction) of the first grain portion Gip.

Referring to FIG. 3A, in addition to the first grain portion G1p, the first grain G1 may further include a grain portion whose crystal orientation is not horizontal. In this case, the crystal orientation of the grain portion may include a vertical direction, but is not limited thereto. In an embodiment, the first ratio occupied by the first grain portion G1p in the first grain G1 may be higher than a second ratio occupied by the grain portion in which the crystal orientation is not horizontal in the first grain G1. In this case, the first and second ratios may be measured as a ratio of numbers. For example, the ratio may be a ratio of a count of the grains in an area, or a ratio of an area occupied by the grains in a cross-sectional sample. In an embodiment, the first ratio may be 50% or more, for example, between about 50% to about 90%, or between about 60% to about 80%. Embodiments are not limited to example ratios of grains, and other ratios may be used.

The crystal orientation of the second grain portion G2p may be substantially perpendicular to the upper surface of the intermediate layer 15. In an embodiment, the crystal orientation of the second grain portion G2p may be a vertical direction (for example, Z-direction). Accordingly, the maximum vertical width G2v of the second grain portion G2p may be greater than the maximum horizontal width G2h. The maximum vertical width G2v may be defined as the maximum value of the width along the vertical direction (for example, Z-direction) of the second grain portion G2p, and the maximum horizontal width G2h may be defined as the maximum value of the width of the second grain portion G2p in one horizontal direction (for example, X-direction and/or Y-direction). From another perspective, the second grain portion G2p may be understood as having a vertical grain structure. In an example, the maximum vertical width G2v of the second grain portion G2p may be greater than the maximum horizontal width G1h of the first grain portion G1p. In the case that the second gate electrode layer 16 is formed by the bottom-up growth method, it may be understood that a crystal orientation of the second grain G2 include the second grain portion G2p may be substantially vertical. In an embodiment, the volume ratio occupied by the second grain portion G2p in the second grain G2 may be 80% or more, for example, between about 80% to about 95%, or between about 90% to about 95%. These volume ratios may be associated a columnar grain structure. For example, the second grain portion G2p may be understood as having the columnar grain structure.

The crystal orientation of the third grain portion Gmp may be substantially perpendicular to the upper surface of the first gate electrode layer 14. In an embodiment, the crystal orientation of the third grain portion Gmp may be a vertical direction (for example, Z-direction). Likewise, the maximum vertical width Gmv of the third grain portion Gmp may be equal to or greater than the maximum horizontal width Gmh. The maximum vertical width Gmv may be defined as the maximum value of the width along the vertical direction (for example, Z-direction) of the third grain portion Gmp, and the maximum horizontal width Gmh may be defined as the maximum value of the width of the third grain portion Gmp along a horizontal direction (for example, X-direction and/or Y-direction). In the case that the intermediate layer 15 is formed by limited deposition on the upper surface of the first gate electrode layer 14, it may be understood that a crystal orientation of the third grain Gm include the third grain portion Gmp may be substantially vertical. In an embodiment, the volume ratio of the third grain portion Gmp to the third grain Gm may be 90% or more, for example, between about 90% to about 99%, or between about 95% to about 99%.

According to an example embodiment, by disposing the intermediate layer 15 having the third grain portion Gmp on the upper surface of the first gate electrode layer 14, a base substrate (for example, the upper surface of the intermediate layer 15) having a more favorable and uniform surface state for bottom-up growth of the second gate electrode layer 16 may be provided. In detail, since the surface of the upper surface of the intermediate layer 15 may be flatter than the surface of the upper surface of the first gate electrode layer 14, and the third grain portion Gmp of the intermediate layer 15 has a substantially vertical crystal orientation, the second gate electrode layer 16 may be uniformly grown bottom-up on the upper surface of the intermediate layer 15 so that growth dispersion is small and surface roughness characteristics may be improved.

The size of each grain of the first gate electrode layer 14, the intermediate layer 15, and the second gate electrode layer 16 may be determined depending on the type of material. For example, when the first gate electrode layer 14 is selected from the group consisting of titanium (Ti) or titanium nitride (TiN), and when the second gate electrode layer 16 is selected from the group consisting of tungsten (W), tungsten nitride (WN), molybdenum (Mo), or molybdenum nitride (MoN), the size of each of the second grains G2 may be larger than the size of each of the first grains G1. For example, the size of the second grain portion G2p may be larger than the size of the first grain portion G21. In this case, the size of the grain portion may mean the volume of the grain portion. Since the materials included in each of the first and second gate electrode layers 14 and 16 are examples, the size relationship between the first and second grains G1 and G2 may be different.

The first gate electrode layer 14 may include at least one first void G1_0 between the first grain portions G1p, and the second gate electrode layer 16 may include at least one second void G2_0 between the second grain portions G2p. In an embodiment, the size of the first void G1_0 may be larger than the size of the second void G2_0. Additionally, the number of first voids G1_0 may be greater than the number of second voids G2_0. From another perspective, the film quality of the second gate electrode layer 16 may be denser than that of the first gate electrode layer 14.

The upper pattern 18 may be disposed between the second gate electrode layer 16 and the gate capping layer 19. The upper pattern 18 may be a semiconductor pattern including polysilicon doped with p-type or n-type impurities. The upper pattern 18 may be called a third gate electrode layer or a polysilicon layer.

The gate capping layer 19 may be disposed on the upper portion of the gate structure GS. The gate capping layer 19 may fill at least a portion of the gate trench T. A portion of the upper surface of the gate capping layer 19 may be coplanar with the upper surface of the device isolation layer 6s, and a portion of the upper surface of the gate capping layer 19 may have a curved surface that is concave upward. The gate capping layer 19 may include silicon nitride.

The buffer layer 21 may be disposed on the active region 6a, the device isolation layer 6s, and the gate structure GS. The buffer layer 21 may include silicon oxide, silicon nitride, or silicon oxynitride, or combinations thereof. The buffer layer 21 may be composed of a single layer or multiple layers.

The bit line structures BLS extend in the Y-direction and may be spaced apart from each other in the X-direction. The bit line structure BLS may have a bar shape extending in the Y-direction. The bit line structure BLS may include a bit line BL and a bit line capping layer 28 on the bit line BL. The bit line BL may include a first conductive layer 25a, a second conductive layer 25b, and a third conductive layer 25c. The first conductive layer 25a, the second conductive layer 25b, and the third conductive layer 25c may be sequentially stacked on the buffer layer 21. The first conductive layer 25a may include polysilicon. The second conductive layer 25b may include a metal-semiconductor compound. For example, the metal-semiconductor compound may be a layer in which a portion of the first conductive layer 25a is silicided. For example, the metal-semiconductor compound may include cobalt silicide (CoSi), titanium silicide (TiSi), nickel silicide (NiSi), tungsten silicide (WSi), or other metal silicides, or may include nitrides such as TiSiN. The third conductive layer 25c may include a metal material such as titanium (Ti), tantalum (Ta), tungsten (W), or aluminum (Al). The bit line BL may be disposed below the first conductive layer 25a. The bit line BL may further include a plug portion 25p extending downward and in contact with the second impurity region 9b. The plug portion 25p may be located within the contact hole H formed on the upper surface of the substrate 3. In plan view, the plug portion 25p may contact the central portion of the active region 6a. The plug portion 25p may electrically connect the active region 6a to the bit line structure BLS. The plug portion 25p may include the same material as the first conductive layer 25a.

The bit line capping layer 28 may include a first insulating layer 28a, a second insulating layer 28b, and a third insulating layer 28c disposed on the bit line BL. The side surface of the first insulating layer 28a may be coplanar with the first conductive layer 25a, the second conductive layer 25b, and the third conductive layer 25c. The first insulating layer 28a, the second insulating layer 28b, and the third insulating layer 28c may include silicon oxide, silicon nitride, silicon oxynitride, or combinations thereof, and for example, may include silicon nitride.

The spacer structures SP may be disposed on both sides of the bit line structures BLS, respectively, and may extend in the Y-direction along the sides of the bit line structures BLS. The spacer structure SP may include a first spacer SP1, a second spacer SP2, a third spacer SP3, and a fourth spacer SP4 disposed on the side surface of the bit line structures BLS. The first spacer SP1 may be conformally disposed along the sides of the bit line structure BLS and the contact hole H. The second spacer SP2 is disposed on the first spacer SP1 and may fill the contact hole H. The third spacer SP3 may cover the side surface of the first spacer SP1, and the fourth spacer SP4 may cover the side surface of the third spacer SP3. The third spacer SP3 and the fourth spacer SP4 may cover the upper surface of the second spacer SP2. The first spacer SP1, the second spacer SP2, the third spacer SP3, and the fourth spacer SP4 may include silicon oxide, silicon nitride, silicon oxynitride, or combinations thereof. In an example embodiment, the first spacer SP1 and the fourth spacer SP4 may include silicon nitride, and the second spacer SP2 may include silicon oxide, and the third spacer SP3 may include an air gap. The spacer structure SP of the present inventive concept is illustrative, and the material and number of layers are not limited thereto and may vary in various manners.

The contact plug 60 is disposed between the bit line structures BLS and may contact the spacer structures SP. Contact plugs 60 may be disposed between bit line structures BLS and between gate structures GS.

The lower end of the contact plug 60 may be located at a lower level than the upper surface of the substrate 3. The upper surface of the contact plug 60 may be located at a lower level than the upper end of the bit line structure BLS. The contact plug 60 may extend into the substrate 3 and may be in contact with the second impurity region 9b of the active region 6a. The contact plug 60 may be electrically connected to the second impurity region 9b. The contact plug 60 may be formed of a conductive material, and may include at least one of, for example, polysilicon (Si), titanium (Ti), titanium nitride (TiN), tantalum (Ta), tantalum nitride (TaN), tungsten (W), tungsten nitride (WN) or aluminum (Al). In an example embodiment, the contact plug 60 may include doped polysilicon and may include n-type impurities such as phosphorus (P), arsenic (As), and antimony (Sb).

The fence structure 63 may be disposed between the bit line structures BLS and may overlap the gate structure GS in a vertical direction. The fence structures 63 may be arranged alternately with the contact plugs 60 along the Y-direction. The fence structures 63 may spatially separate the contact plugs 60 from each other and electrically insulate the contact plugs 60 from each other. The lower surface of the fence structure 63 may be in contact with the gate capping layer 19 of the gate structure GS. In an example embodiment, the lower surface of the fence structure 63 may have a curved surface that is downwardly convex toward the gate capping layer 19, and the upper surface of the gate capping layer 19 may have a curved surface that is concave upward. The lower surface of the fence structure 63 may be located at a lower level than the upper surface of the substrate 3. The fence structure 63 may include an insulating material, for example, silicon nitride.

The semiconductor device 100 may further include a metal-semiconductor compound layer 66 disposed on the upper surface of the contact plug 60. The metal-semiconductor compound layer 66 may contact the side surface of the spacer structure SP and the side surface of the fence structure 63.

The landing pad 69 may be disposed on metal-semiconductor compound layer 66, and may include a barrier layer 69a covering the bit line structure BLS, the spacer structure SP and the fence structure 63, and a metal layer 69b on the barrier layer 69a. The landing pad 69 may be electrically connected to the second impurity region 9b of the active region 6a through the contact plug 60. The metal-semiconductor compound layer 66 may include cobalt silicide (CoSi), titanium silicide (TiSi), nickel silicide (NiSi), tungsten silicide (WSi), or other metal silicide. The barrier layer 69a may include at least one of metal nitride, for example, titanium nitride (TiN), tantalum nitride (TaN), or tungsten nitride (WN). The metal layer 69b may include at least one of a conductive material, for example, titanium (Ti), tantalum (Ta), tungsten (W), or aluminum (Al).

The semiconductor device 100 may further include an upper insulating spacer 50 that covers the bit line structure BLS, the spacer structure SP, and the fence structure 63. The upper insulating spacer 50 may be disposed between the bit line structure BLS and the barrier layer 69a, between the spacer structure SP and the barrier layer 69a, and between the fence structure 63 and the barrier layer 69a.

The semiconductor device 100 may further include an insulating pattern 72 disposed between the landing pads 69. The upper surface of the insulating pattern 72 may be coplanar with the upper surface of the landing pad 69, and the insulating pattern 72 may extend downward and partially contact the bit line structures BLS. The insulating pattern 72 may spatially separate the landing pads 69 from each other and electrically insulate them from each other.

The semiconductor device 100 may further include an etch stop layer 75 covering the upper surface of the landing pad 69 and the insulating pattern 72. The capacitor structure 80 may be disposed on the landing pad 69 and the insulating pattern 72. Capacitor structure 80 may include a lower electrode 82, a capacitor dielectric layer 84, and an upper electrode 86. The lower electrode 82 may penetrate the etch stop layer 75 and contact the upper surface of the landing pad 69. The capacitor dielectric layer 84 may cover the lower electrode 82 and the etch stop layer 75, and the upper electrode 86 may cover the capacitor dielectric layer 84. The capacitor structure 80 may be electrically connected to the landing pad 69 and the contact plug 60. The lower electrode 82 and the upper electrode 86 may include at least one of a doped semiconductor, metal nitride, metal, or metal oxide. The lower electrode 82 and the upper electrode 86 may include at least one of, for example, polycrystalline silicon, titanium nitride (TiN), tungsten (W), titanium (Ti), ruthenium (Ru), or tungsten nitride (WN). For example, the capacitor dielectric layer 84 may include at least one of high dielectric constant materials such as zirconium oxide (ZrO₂), aluminum oxide (Al₂O₃), or hafnium oxide (Hf₂O₃).

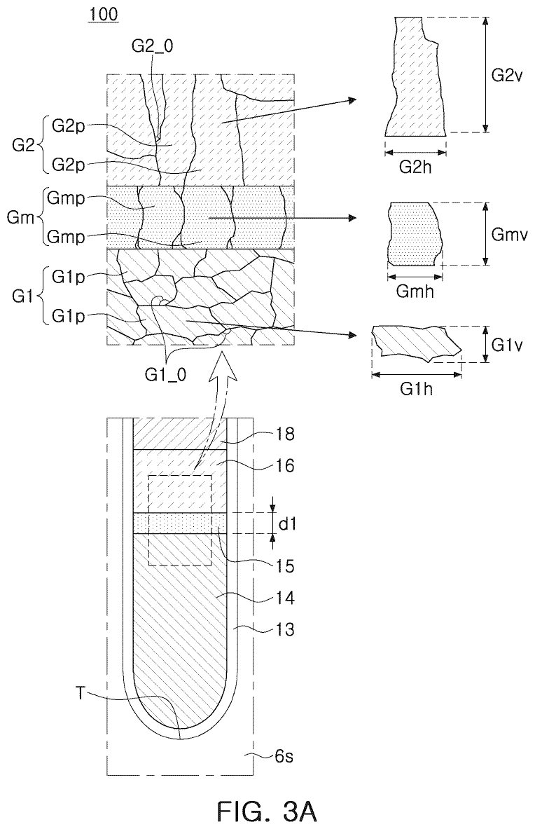

FIG. 4 is a partial enlarged view illustrating a semiconductor device according to example embodiments.

Referring to FIG. 4, a semiconductor device 100a may be the same or similar to that described with reference to FIGS. 1, 2A to 2C, and 3A to 3B. As show in FIG. 4, the thickness of the intermediate layer 15 may be thinner than the thickness of the gate dielectric layer 16.

Referring to FIG. 4, the vertical thickness of the intermediate layer 15 along the Z-direction may be smaller than the horizontal thickness of the gate dielectric layer 13 along the Y-direction. Accordingly, the thickness of the intermediate layer 15 may be smaller than the thickness of the first and second gate electrode layers 14 and 16 and the gate dielectric layer 13. In an example, the thickness d1 of intermediate layer 15 may range from approximately 5 Å to approximately 30 Å. In an example, the thickness d1 of intermediate layer 15 may range from approximately 5 Å to approximately 20 Å.

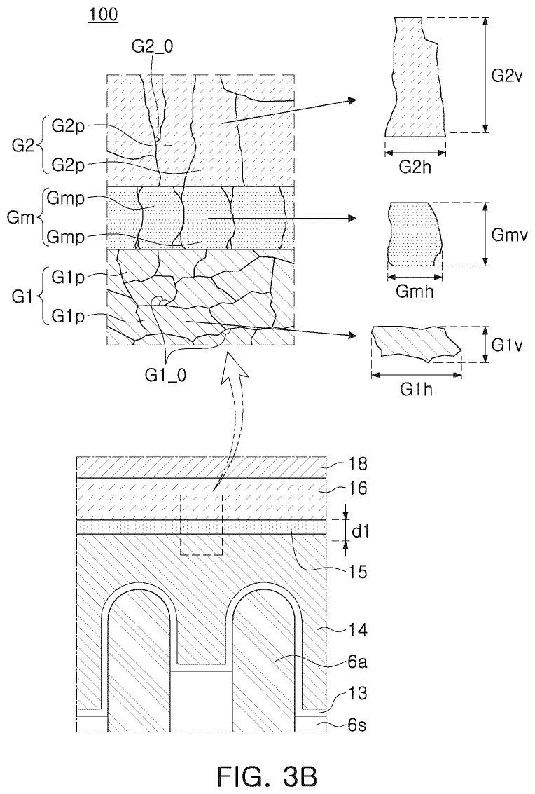

FIG. 5 is a partial enlarged view illustrating a semiconductor device according to example embodiments.

Referring to FIG. 5, a semiconductor device 100b may be the same or similar to that described with reference to FIGS. 1, 2A to 2C, 3A to 3B, and 4. As shown in FIG. 5, the upper surface 14US of the first gate electrode layer 14 may have a downwardly convex shape in the direction toward the upper surface of the substrate.

Referring to FIG. 5, the upper surface 14US of the first gate electrode layer 14 may have a downwardly convex shape in a direction toward the upper surface of the substrate or the lower region of the trench T. Accordingly, the lower surface 15LS of the intermediate layer 15 in contact with the upper surface 14US of the first gate electrode layer 14 may also have a downwardly convex shape in the direction toward the lower region of the trench T.

The upper surface 14US of the first gate electrode layer 14 may have a gentler curve than the lower surface 14LS of the first gate electrode layer 14. The lower surface 14LS of the first gate electrode layer 14 may be defined as a surface having a downwardly convex shape in the lower region of the trench T. From another perspective, the curvature of the upper surface 14US of the first gate electrode layer 14 may be smaller than the curvature of the lower surface 14LS of the first gate electrode layer 14.

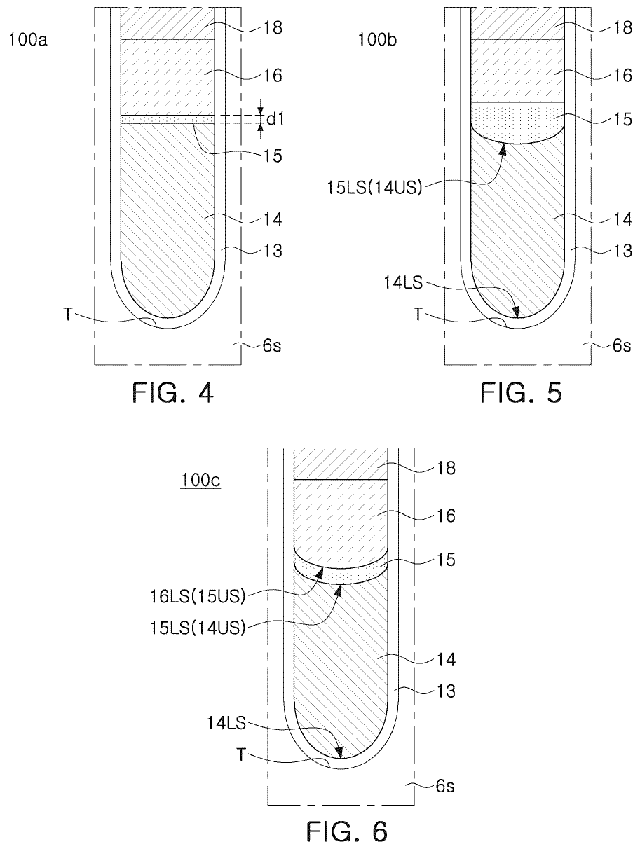

FIG. 6 is a partial enlarged view illustrating a semiconductor device according to example embodiments.

Referring to FIG. 6, the semiconductor device 100c may be the same or similar to that described with reference to FIGS. 1, 2A to 2C, 3A to 3B, 4, and 5. As shown in FIG. 6, the intermediate layer 15 may have a downwardly convex shape in the direction toward the center of the first gate electrode layer 14.

Referring to FIG. 6, an upper surface 15US and a lower surface 15LS of the intermediate layer 15 may have a downwardly convex shape in a direction toward the center of the first gate electrode layer 14. Accordingly, the lower surface 16LS of the second gate electrode layer 16 in contact with the upper surface 15US of the intermediate layer 15 may also have a downwardly convex shape.

The upper and lower surfaces 15US and 15LS of the intermediate layer 15 may have a gentler curve than the lower surface 14LS of the first gate electrode layer 14. From another perspective, the curvature of each of the upper and lower surfaces 15US and 15LS of the intermediate layer 15 may be smaller than the curvature of the lower surface 14LS of the first gate electrode layer 14.

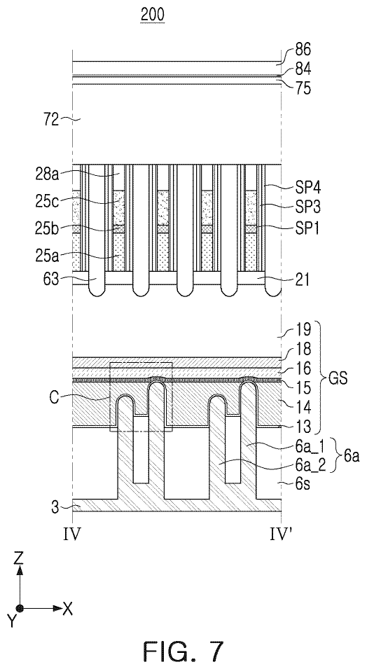

FIG. 7 is a vertical cross-sectional view illustrating a semiconductor device according to an example embodiment. FIG. 7 is a vertical cross-sectional view taken along line IV-IV′ of the semiconductor device illustrated in FIG. 1.

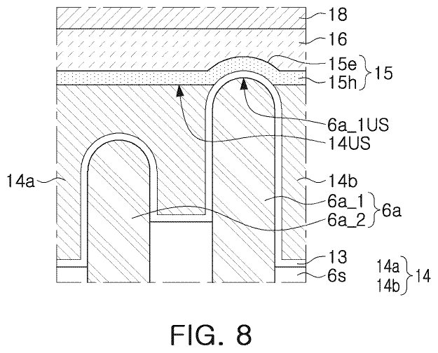

FIG. 8 is an enlarged view of a portion of the semiconductor device illustrated in FIG. 7. FIG. 8 may correspond to area ‘C’ in FIG. 7.

Referring to FIG. 7 and FIG. 8, a semiconductor device 200 may be the same or similar to that described with reference to FIGS. 1 to 6. In FIG. 7 and FIG. 8 it may be shown that at least some of the active regions 6a (6a_1) may protrude in a vertical direction upward from the upper surface of the first gate electrode layer 14. Accordingly, descriptions of parts that are the same as those described with reference to FIGS. 1 to 6 may be omitted or simplified.

Referring to FIG. 7 and FIG. 8, the active regions 6a may include first active regions 6a_1 and second active regions 6a_2 having upper surfaces located at different levels from the upper surface of the substrate 3.

The upper surface 6a_1US of the first active region 6a_1 may be disposed at a higher level relative to the upper surface of the substrate 3 than the upper surface of the second active region 6a_2. From another perspective, the upper region of the first active region 6a_1 may be positioned to protrude upward from the upper surface 14US of the first gate electrode layer 14 in a vertical direction (for example, Z-direction). A portion of the first active region 6a_1 that protrudes from the upper surface 14US of the first gate electrode layer 14 may be called a protrusion. The first gate electrode layer 14 may have portions 14a and 14b spaced apart in the X-direction with the protrusion disposed therebetween.

The intermediate layer 15 may include a horizontal portion 15h on the upper surface 14US of the first gate electrode layer 14, and an extended portion 15e extending from the horizontal portion 15h to cover the protrusion (or the gate dielectric layer 13 on the protrusion) of the first active region 6a_1. The intermediate layer 15 may be formed conformally on the upper surface 14US and the protrusion.

According to an example embodiment, the plurality of portions 14a and 14b spaced apart in the X-direction by the protrusion may be reconnected to each other by the intermediate layer 15. In detail, by disposing the intermediate layer 15 on the first gate electrode layer 14 and the active region 6a, the first gate electrode layer 14 may be isolated from the active regions 6a and 6a_1. For example, by disposing the intermediate layer 15 on the first gate electrode layer 14 and the active region 6a, the first gate electrode layer 14 may be prevented from being physically or electrically disconnected by the active regions 6a and 6a_1.

According to an example embodiment, the protrusions of the active region 6a_1 may be covered by an intermediate layer 15, and the second gate electrode layer 16 may be grown bottom-up substantially uniformly on the first gate electrode layer 14 without physical or electrical interruption due to the protrusion.

According to an example, the upper surface of the portion of the second gate electrode layer 16 disposed on the extended portion 15e may have an upwardly convex shape (not illustrated).

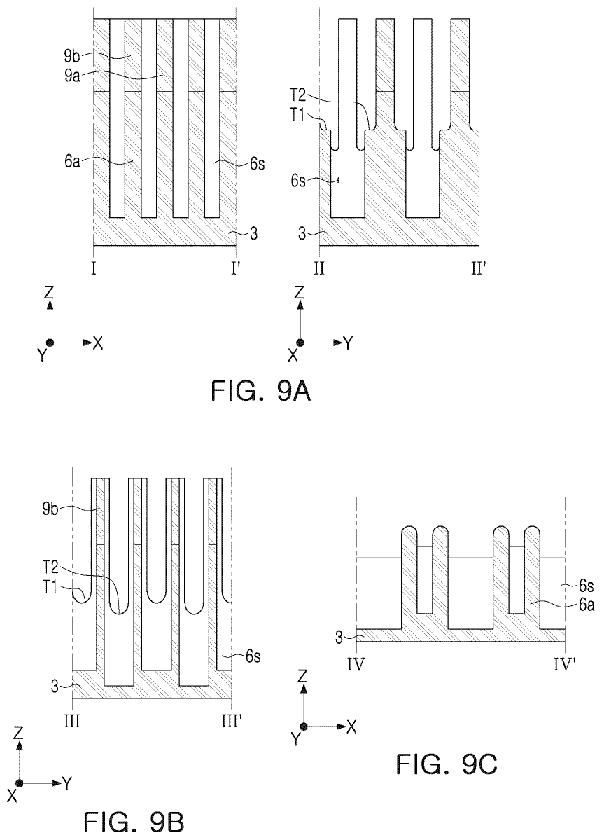

FIGS. 9A to 9C, 10A to 10C, 11A to 11C, 12A to 12C, 13A to 13C, 14A to 14C, and 15A to 15C are vertical cross-sectional views illustrated according to the process sequence to illustrate a method of manufacturing a semiconductor device according to an example embodiment.

Referring to FIGS. 9A to 9C, a device isolation layer 6s and a plurality of gate trenches T1 and T2 may be formed in the substrate 3.

The device isolation layer 6s may be formed by forming a trench on the upper surface of the substrate 3, filling the trench with an insulating material, and performing a planarization process of etching the substrate 3 and the insulating material. The device isolation layer 6s may define active regions 6a. For example, the active regions 6a may correspond to a portion of the upper surface of the substrate 3 surrounded by the device isolation layer 6s. In plan view, the active regions 6a may have a bar shape with a minor axis and a major axis and may be spaced apart from each other. The device isolation layer 6s may be composed of a single layer or multiple layers.

In an example embodiment, the first and second impurity regions 9a and 9b may be formed by injecting impurities into the substrate 3 before the device isolation layer 6s is formed. However, depending on an embodiment, the first and second impurity regions 9a and 9b may be formed after forming the device isolation layer 6s or at another process step.

Thereafter, the substrate 3 may be anisotropically etched to form gate trenches T1 and T2. The gate trenches T1 and T2 extend in the X-direction and may cross the active region 6a and the device isolation layer 6s.

In an example embodiment, the gate trenches T1 and T2 may have different depths. For example, the lower end of the gate trench T2 may be disposed at a lower level than the lower end of the gate trench T1. In an example embodiment, the gate trenches T1 and T2 may be formed sequentially. For example, the gate trenches T2 may be formed after the gate trenches T1 are formed, and the gate trenches T1 may be formed after the semi-second gate trenches T2 are formed. Gate trenches T1 and T2 may be formed alternately along the Y-direction. Without being limited, the depths of the gate trenches T1 and T2 may be substantially the same (not illustrated). The gate trenches T1 and T2 may be collectively referred to as gate trenches T.

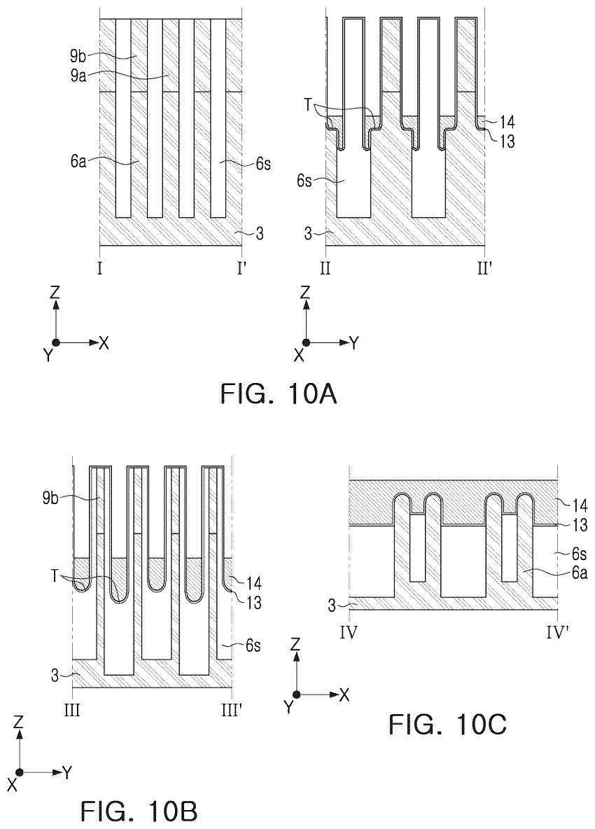

Referring to FIGS. 10A, 10B, and 10C, the gate dielectric layer 13 may be formed on the structure in which the gate trenches T are formed. For example, the gate dielectric layer 13 may be conformally formed on the structure in which the gate trenches T are formed. The first gate electrode layer 14 may be formed by forming a conductive material on the gate dielectric layer 13, and sequentially performing a planarization process and an etch-back process. The gate trenches T thus formed may be collectively referred to as gate trenches T. In an embodiment, the first gate electrode layer 14 may be formed by chemical vapor deposition (CVD), but is not limited thereto.

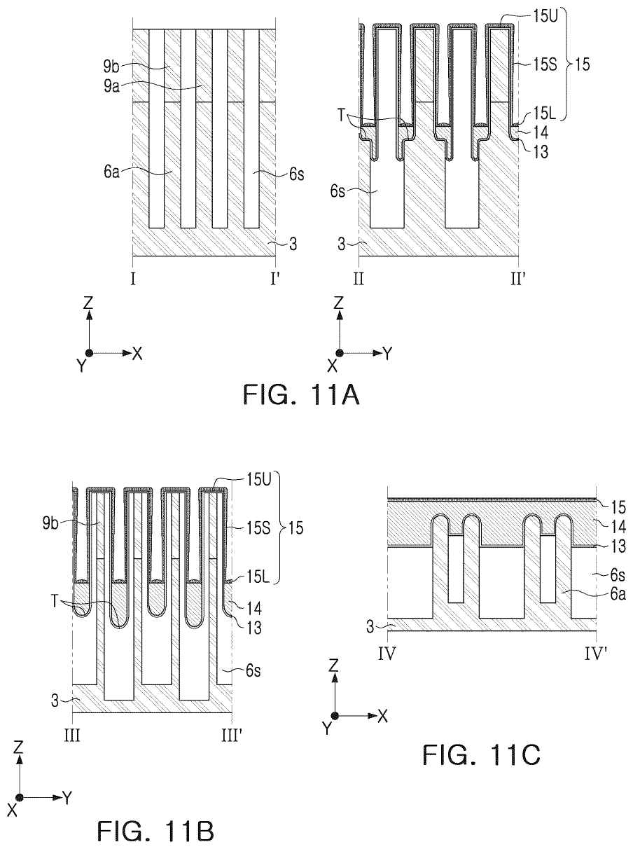

Referring to FIGS. 11A, 11B, and 11C, an intermediate layer 15 may be formed on the gate dielectric layer 13.

The intermediate layer 15 may be formed by depositing a conductive material on the gate dielectric layer 13. The intermediate layer 15 may be formed by physical vapor deposition (PVD), but is not limited thereto.

The intermediate layer 15 may be defined to include a lower portion 15L, a middle portion 15S, and an upper portion 15U. The lower portion 15L may be disposed on the upper surface of the first gate electrode layer 14. The middle portion 15S may be disposed on the gate dielectric layer 13. The upper portion 15U may be disposed on the impurity regions 9a and 9b. An end of the upper portion 15U may be formed to protrude beyond the surface of the middle portion 15S. An upper surface of the lower portion 15L may have an upwardly convex shape, and accordingly, both end portions of the lower portion 15L may be formed to have a thickness thinner than a middle portion thereof. The middle portion 15S of the intermediate layer 15 may extend downward from the upper portion 15U and may contact the lower portion 15L on sides of the impurity regions 9a and 9b. The middle portion 15S may be formed to have a thickness that becomes thinner as it extends downward. The thickness of the middle portion 15S may be thinner than the thickness of each of the lower portion 15L and the upper portion 15U.

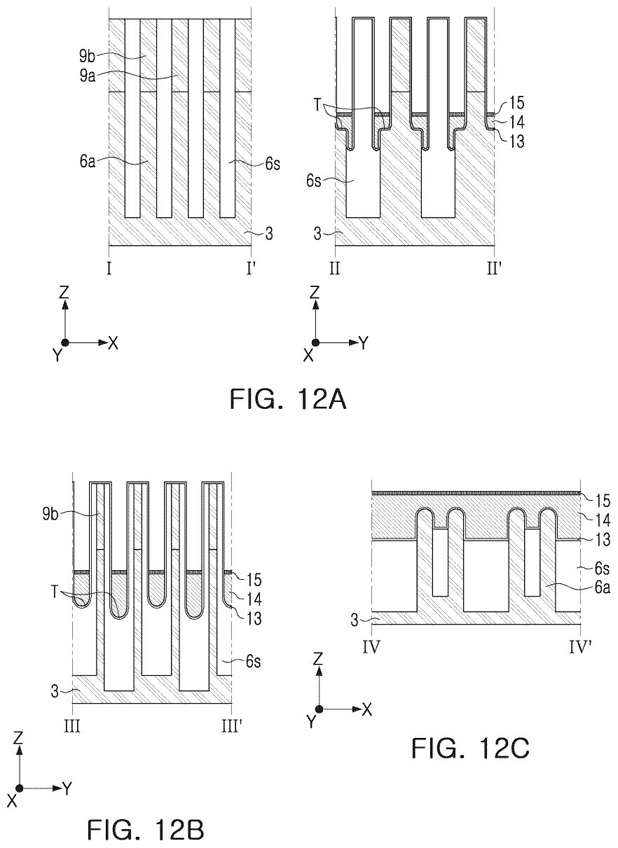

Referring to FIGS. 12A, 12B, and 12C, the middle portion 15S and the upper portion 15U of the intermediate layer 15 may be removed. For example, the middle portion 15S and the upper portion 15U of the intermediate layer 15 may be removed using a wet etching process.

The lower portion 15L may remain through the wet etching process using the difference in etch selectivity between the gate dielectric layer 13, the middle portion 15S, and the upper portion 15U.

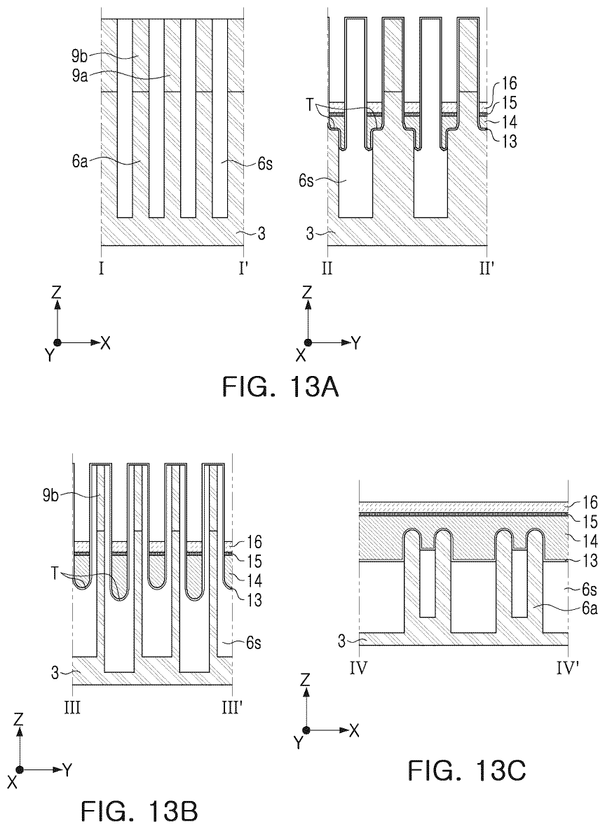

Referring to FIGS. 13A, 13B, and 13C, a second gate electrode layer 16 may be disposed in the gate trenches T. The second gate electrode layer 16 may be formed by selectively depositing a conductive material on the upper surface of the intermediate conductive layer 15 and growing it from the bottom up. In an embodiment, the second gate electrode layer 16 may be formed by, for example, area-selective atomic layer deposition (AS-ALD), but is not limited thereto.

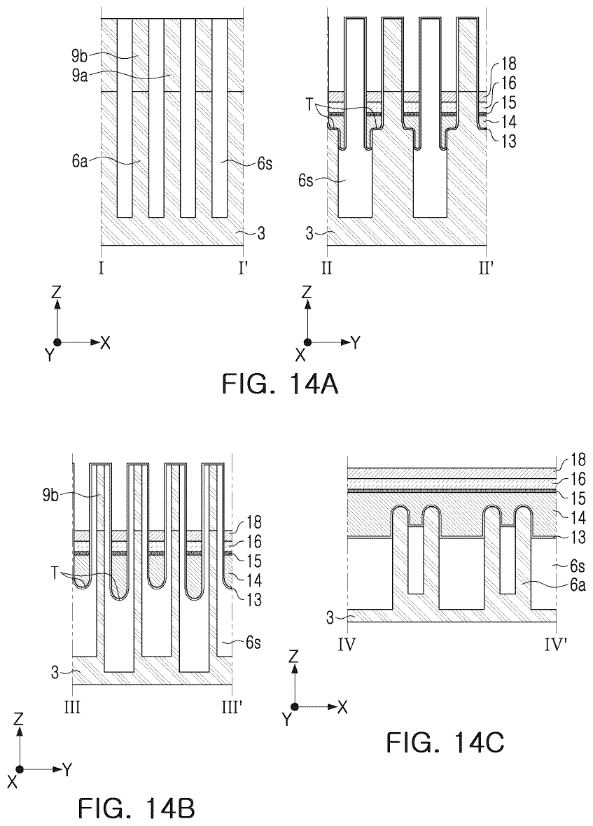

Referring to FIGS. 14A, 14B, and 14C, a polysilicon layer forming the upper pattern 18 may be disposed in the gate trenches T. The polysilicon layer forming the upper pattern 18 may be formed by forming polysilicon on the second gate electrode layer 16 to fill the gate trenches T and then sequentially performing a planarization process and an etch-back process on the polysilicon.

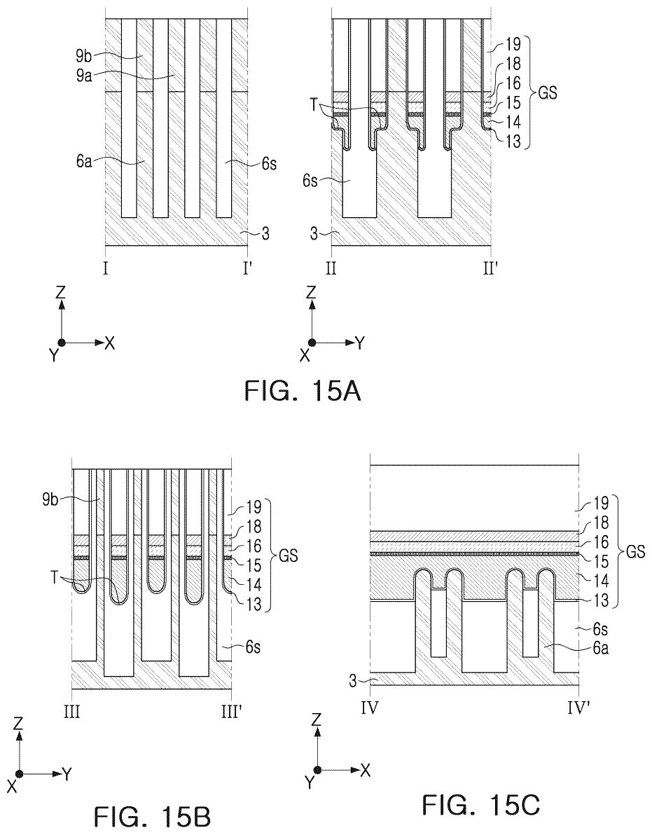

Referring to FIGS. 15A, 15B, and 15C, a gate structure GS may be formed by forming a gate capping layer 19 in the gate trenches T. The gate capping layer 19 may be formed by forming an insulating material on the polysilicon layer forming the upper pattern 18. The gate capping layer 19 may be disposed to fill at least a portion of the gate trenches T1. A planarization process may be performed to planarize the gate capping layer 19.

As set forth herein, according to example embodiments, a semiconductor device including a gate electrode layer may be provided in which at least one of physical breakage, surface roughness, or growth distribution deterioration may be improved.

In detail, according to example embodiments, degradation of a semiconductor device including a gate electrode layer may be inhibited or prevented by disposing an intermediate layer containing a conductive material, between two vertically stacked gate electrode layers.

While example embodiments have been illustrated and described herein, it will be apparent to those skilled in the art that modifications and variations could be made without departing from the scope of the present disclosure as defined by the appended claims.

What is claimed is:

1. A semiconductor device comprising:
a substrate comprising an active region;
a gate trench disposed in the substrate, the gate trench extending across the active region in a first horizontal direction; and
a gate structure disposed in the gate trench,
wherein the gate structure comprises,
a buried gate electrode disposed in the gate trench;
a gate capping layer disposed in the gate trench on the buried gate electrode; and
a gate dielectric layer disposed between the buried gate electrode and the gate trench and between the gate capping layer and the gate trench,
the buried gate electrode comprises,
a first gate electrode layer;
a second gate electrode layer disposed on the first gate electrode layer; and
an intermediate conductive layer disposed between the first gate electrode layer and the second gate electrode layer.

2. The semiconductor device of claim 1, wherein the gate structure further includes a third gate electrode layer disposed between the second gate electrode layer and the gate capping layer,
wherein a side surface of the first gate electrode layer, a side surface of the second gate electrode layer, a side surface of the intermediate conductive layer, and a side surface of the third gate electrode layer is in contact with the gate dielectric layer.

3. The semiconductor device of claim 2, wherein the third gate electrode layer comprises polysilicon.

4. The semiconductor device of claim 1, wherein the first gate electrode layer comprises a first TiN,
the intermediate conductive layer comprises a second TiN different from the first TiN, and the second gate electrode layer comprises at least one of W or Mo.

5. The semiconductor device of claim 4, wherein the first TiN comprises a grain portion in which a crystal orientation is horizontal, and
the second TiN comprises a grain portion in which a crystal orientation is perpendicular to an upper surface of the first gate electrode layer.

6. The semiconductor device of claim 1, wherein the first gate electrode layer comprises first grains,
the second gate electrode layer comprises second grains, and
a size of each of the second grains is larger than a size of each of the first grains.

7. The semiconductor device of claim 1, wherein the first gate electrode layer comprises a first grain portion,
the second gate electrode layer comprises a second grain portion,
a maximum horizontal width of the first grain portion is equal to or greater than a maximum vertical thickness of the first grain portion, and
a maximum vertical thickness of the second grain portion is greater than a maximum horizontal width of the second grain portion.

8. The semiconductor device of claim 7, wherein the maximum vertical thickness of the second grain portion is greater than the maximum horizontal width of the first grain portion.

9. The semiconductor device of claim 1, wherein the intermediate conductive layer comprises a third grain portion,
wherein a maximum vertical thickness of the third grain portion is equal to or greater than a maximum horizontal width of the third grain portion.

10. The semiconductor device of claim 1, wherein a thickness of the intermediate conductive layer is thinner than a thickness of the first gate electrode layer and thinner than a thickness of the second gate electrode layer.

11. The semiconductor device of claim 1, wherein a thickness of the intermediate conductive layer is thinner than a thickness of the gate dielectric layer.

12. The semiconductor device of claim 1, wherein a thickness of the intermediate conductive layer is about 5 Angstroms (Å) or more and about 30 Å or less.

13. The semiconductor device of claim 1, wherein the first gate electrode layer has a shape in which an upper surface the first gate electrode layer is downwardly convex.

14. The semiconductor device of claim 1, wherein the intermediate conductive layer has a convex shape in a direction toward the first gate electrode layer.

15. A semiconductor device comprising:
a substrate including active regions;
a gate structure extending across the active regions of the substrate in a first horizontal direction; and
a bit line structure extending across the gate structure in a second horizontal direction, intersecting the first horizontal direction,
wherein the gate structure comprises,
a first gate electrode layer disposed on the substrate;
an intermediate conductive layer disposed on the first gate electrode layer; and
a second gate electrode layer disposed on the intermediate conductive layer, and
the intermediate conductive layer comprises a grain portion having a crystal orientation that is substantially perpendicular to an upper surface of the first gate electrode layer.

16. The semiconductor device of claim 15, wherein at least some of the active regions have a protrusion protruding in a vertical direction from the upper surface of the first gate electrode layer, and
the intermediate conductive layer comprises a horizontal portion on the upper surface of the first gate electrode layer and an extension portion extending from the horizontal portion and covering the protrusion.

17. The semiconductor device of claim 15, wherein the first gate electrode layer comprises a first metal grain having a first metal grain portion, and
the second gate electrode layer comprises a second metal grain having a second metal grain portion,
wherein the first metal grain portion has a crystal orientation substantially parallel to an upper surface of the substrate, and
the second metal grain portion has a crystal orientation substantially perpendicular to an upper surface of the intermediate conductive layer.

18. The semiconductor device of claim 15, wherein a film quality of the second gate electrode layer is denser than a film quality of the first gate electrode layer.

19. A semiconductor device comprising:
a substrate including an active region;
a gate trench disposed in the substrate, the gate trench extending across the active region in a first horizontal direction;
a gate structure disposed in the gate trench;
a bit line structure extending across the gate structure in a second horizontal direction, intersecting the first horizontal direction;
a contact plug disposed on a side surface of the bit line structure;
a landing pad disposed on the contact plug; and
a capacitor structure electrically connected to the landing pad,
wherein the gate structure comprises,
a buried gate electrode disposed in the gate trench;
a gate capping layer disposed in the gate trench and on the buried gate electrode; and
a gate dielectric layer disposed between the buried gate electrode and the gate trench and between the gate capping layer and the gate trench,
the buried gate electrode comprises,
a first gate electrode layer;
a second gate electrode layer on an upper surface of the first gate electrode layer;
a third gate electrode layer on an upper surface of the second gate electrode layer; and
an intermediate conductive layer between the upper surface of the first gate electrode layer and a lower surface of the second gate electrode layer,
wherein a side surface of the first gate electrode layer, a side surface of the second gate electrode layer, a side surface of the third gate electrode layer, and a side surface of the intermediate conductive layer are in contact with the gate dielectric layer,
the first gate electrode layer comprises a first TiN comprising a grain portion having a crystal orientation substantially parallel to an upper surface of the substrate, and
the intermediate conductive layer comprises a second TiN different from the first TiN and comprising a grain portion having a crystal orientation substantially perpendicular to the upper surface of the substrate.

20. The semiconductor device of claim 19, wherein the second gate electrode layer comprises at least one of W or Mo including a grain portion having a crystal orientation substantially perpendicular to an upper surface of the substrate.
